(19) United States
(12) Patent Application Publication
(10) Pub. No.: US 2023/0099451 A1
(43) Pub. Date: Mar. 30, 2023

(54) METHOD OF MANUFACTURING SEMICONDUCTOR DEVICE, SUBSTRATE PROCESSING SYSTEM, AND NON-TRANSITORY COMPUTER-READABLE RECORDING MEDIUM

(71) Applicant: Kokusai Electric Corporation, Tokyo (JP)

(72) Inventors: Norihito SHINOZAWA, Toyama-shi (JP); Osamu UEDA, Toyama-shi (JP); Takanori KYOGOKU, Toyama-shi (JP); Kazuhide ASAI, Toyama-shi (JP)

(73) Assignee: Kokusai Electric Corporation, Tokyo (JP)

(21) Appl. No.: 17/951,438

(22) Filed: Sep. 23, 2022

(30) Foreign Application Priority Data
Sep. 24, 2021 (JP) 2021-156016

(51) Int. Cl. H01L 21/66; H01L 21/02; C23C 16/52; C23C 16/455

(52) U.S. Cl. CPC H01L 22/20; H01L 21/0228; C23C 16/52; C23C 16/45525

(57) ABSTRACT

There is provided a technique that includes: processing a substrate according to a processing condition of the substrate; collecting atmospheric pressure data in parallel with the processing of the substrate; adjusting the processing condition of the substrate using the collected atmospheric pressure data; and performing control of the substrate processing according to the processing condition.

### FIELD

The present disclosure relates to a method of manufacturing a semiconductor device, a substrate processing system, and a non-transitory computer-readable recording medium.

### DESCRIPTION OF THE RELATED ART

A controller of a substrate processing apparatus saves a file (hereinafter referred to as “recipe”) indicating a procedure and condition for forming a semiconductor on a substrate (for example, temperature, gas flow rate, pressure, etc. used for film formation) in a storage device such as a memory card or a disk. A plurality of types of recipes are prepared according to a type of film formation (for example, a thickness of a film). A user causes the controller to read an optimum recipe according to a type of semiconductor device to be manufactured, and executes the optimum recipe, thereby performing film formation of a semiconductor. However, an expected film formation result may not be obtained due to an external factor such as fluctuation in atmospheric pressure.

As a general method for addressing the fluctuation in atmospheric pressure, as in technology described in JP H11-195566 A, a method is performed in which a current atmospheric pressure is measured before executing a recipe, an optimum film formation time according to the atmospheric pressure is calculated, a film formation step time in the recipe is amended, and then the recipe is started. However, in the case of a recipe that requires a long film formation time, there is a high possibility that the atmospheric pressure will fluctuate greatly during a film formation process. In this case, it may be difficult to obtain a film formation result expected for the recipe only by amending the film formation step time before start of the recipe as in a conventional case.

### SUMMARY

According to the present disclosure, there is provided a technique capable of obtaining an expected film formation result by causing a recipe to correspond to a fluctuation of atmospheric pressure generated during a film formation process.

According to an aspect of the present disclosure, technology including

processing a substrate according to a processing condition of the substrate,

collecting atmospheric pressure data in parallel with the processing of the substrate,

adjusting the processing condition of the substrate using the collected atmospheric pressure data, and

performing control of the substrate processing according to the processing condition is provided.

### BRIEF DESCRIPTION OF THE DRAWINGS

FIG. 1 is a block diagram illustrating a substrate processing system of an embodiment.

FIG. 2 is a block diagram illustrating an outline of a substrate processing apparatus in the block diagram of FIG. 1.

FIG. 3 is a block diagram illustrating an outline of a group management apparatus in the block diagram of FIG. 1.

FIG. 4 is a perspective view schematically illustrating an example of the substrate processing apparatus.

FIG. 5 is a schematic configuration diagram of a process furnace in the substrate processing apparatus of FIG. 4.

FIG. 6 is a cross-sectional view of the process furnace of FIG. 5.

FIG. 7 is a schematic diagram illustrating each step of a conventional film formation process in chronological order.

FIG. 8 is a schematic diagram illustrating each step of a film formation process of the present disclosure in chronological order.

FIG. 9 is a graph of an outline of a step time adjustment model.

FIG. 10 is a graph of an example of a relationship between a film formation time and a thickness of film.

FIG. 11 illustrates a flowchart of a method of manufacturing a semiconductor device according to an embodiment.

FIG. 12 illustrates a sequence diagram of the method of manufacturing the semiconductor device according to the embodiment.

### DETAILED DESCRIPTION

Hereinafter, embodiments of the present disclosure will be described with reference to the drawings. It should be noted that each drawing is only a schematic diagram, and a size of each part and a ratio of sizes between parts illustrated in the drawings may not reflect an actual device. Further, reference symbols appearing in common in each figure indicate a common component even when the reference symbols are not mentioned in the description of each figure.

(1) Substrate Processing System

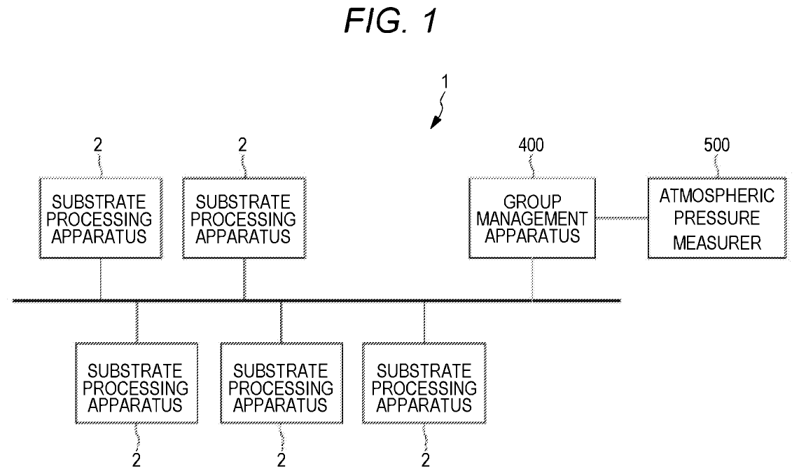

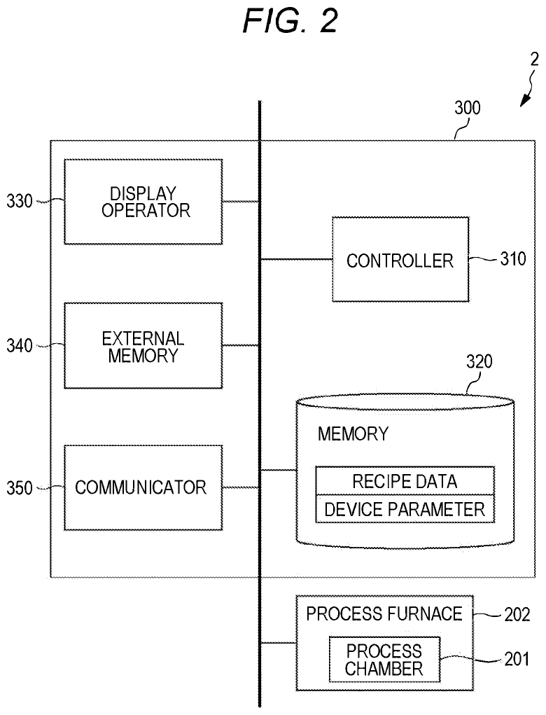

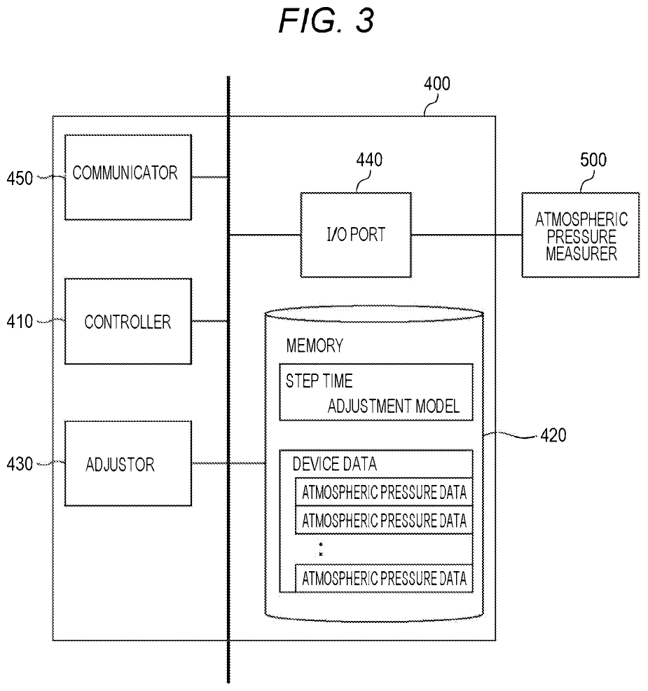

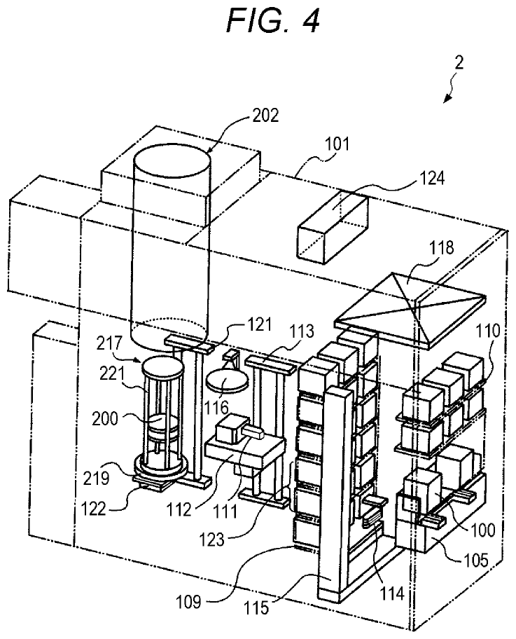

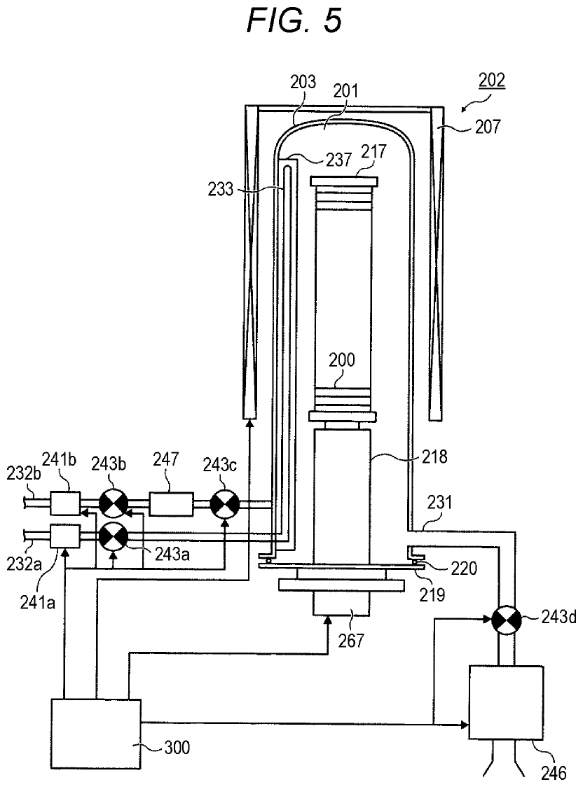

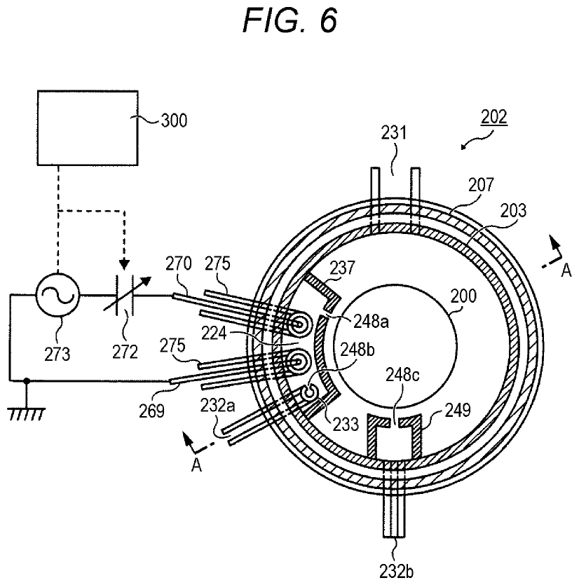

FIG. 1 is a block diagram illustrating a substrate processing system of an embodiment. FIG. 2 is a block diagram illustrating an outline of a substrate processing apparatus in the block diagram of FIG. 1. FIG. 3 is a block diagram illustrating an outline of a group management apparatus in the block diagram of FIG. 1. FIG. 4 is a perspective view schematically illustrating an example of the substrate processing apparatus. FIG. 5 is a schematic configuration diagram of a process furnace in the substrate processing apparatus of FIG. 4. FIG. 6 is a cross-sectional view of the process furnace of FIG. 5.

As illustrated in FIG. 1, a substrate processing system 1 includes a plurality of substrate processing apparatuses 2, a group management apparatus 400, and an atmospheric pressure measurer 500, which are connected to each other via a network. As illustrated in FIG. 2, each of the substrate processing apparatuses 2 includes a process furnace 202 provided with a process chamber 201 (see FIG. 5), and a main controller 300 for controlling processing of a substrate in the process furnace 202. The main controller 300 includes a controller 310, a memory 320, a display operator 330, an external memory 340, and a communicator 350. The controller 310 includes a CPU, and executes a control program of the process furnace 202 stored in the memory 320 based on various data such as recipe data serving as a substrate processing condition and a device parameter stored in the memory 320 and the external memory 340. The display operator 330 is an interface when a user operates the main controller 300. The communicator 350 communicates with the group management apparatus 400 described later.

The group management apparatus 400 includes a controller 410, a memory 420, an adjustor 430, a communicator 450 that communicates with the main controller 300, and an I/O port 440 to which an external device is connected. An atmospheric pressure measurer 500 is connected to the group management apparatus 400 via the I/O port 440. The controller 410 includes a CPU and executes a control program of the group management apparatus 400 stored in the memory 420. In addition to the control program of the group management apparatus 400, the memory 420 stores a step time adjustment model described later, and stores atmospheric pressure data input from the atmospheric pressure measurer 500 via the I/O port 440 as device data used to adjust recipe data serving as a processing condition of a substrate. The adjustor 430 applies the device data stored in the memory 420 to the step time adjustment model, and adjusts the recipe data. The communicator 450 transmits the recipe data adjusted by the adjustor 430 to the main controller 300. The controller 310 of the main controller 300 receiving the recipe data adjusts the recipe data and controls the process furnace 202 based on the recipe data.

A configuration of the substrate processing apparatus 2 of the present embodiment will be described with reference to FIG. 4. As illustrated in FIG. 4, the substrate processing apparatus 2 of the present disclosure, in which a cassette 100 containing a plurality of substrates 200 made of silicon, etc. is used, includes a housing 101. A cassette stage (substrate container delivery table) 105 is installed in cassette loading/unloading opening (not illustrated) inside the housing 101. The cassette 100 is loaded onto the cassette stage 105 by an in-step transfer device (not illustrated) and is unloaded from the cassette stage 105. The cassette stage 105 is placed such that the substrates 200 in the cassette 100 are in a vertical posture and a substrate loading/unloading port of the cassette 100 faces upward by the in-step transfer device. The cassette stage 105 is configured to be operable to rotate the cassette 100 clockwisely in the longitudinal direction by 90° toward the rear of the housing to make the substrates 200 in the cassette 100 be in a horizontal posture and the substrate loading/unloading port of the cassette 100 face the rear of the housing.

A cassette shelf (substrate container mounting shelf) 109 is installed in a substantially central portion in a front-rear direction in the housing 101, and the cassette shelf 109 is configured to store a plurality of the cassettes 100 in a plurality of rows and columns. The cassette shelf 109 is provided with a transfer shelf 123 in which the cassette 100 is stored. In addition, a spare cassette shelf 110 is provided above the cassette stage 105, and is configured to preliminarily store the cassette 100. A cassette elevator (substrate container elevating mechanism) 115 capable of raising and lowering the cassette 100 while holding the cassette 100 and a cassette transfer machine 114 are configured between the cassette stage 105 and the cassette shelf 109, and the cassette 100 is configured to be transferred between the cassette stage 105, the cassette shelf 109, and the spare cassette shelf 110 by a continuous operation of the cassette elevator 115 and the cassette transfer machine 114.

A substrate transfer machine 112 capable of rotating or translating the substrates 200 in the horizontal direction and a transfer elevator 113 for lifting and lowering the substrate transfer machine 112 are configured behind the cassette shelf 109. The transfer elevator 113 is installed in a right-side end portion of the housing 101. The transfer elevator 113 and the substrate transfer machine 112 are configured to charge and discharge, by its continuous operation, the substrates 200 onto/from a board (substrate retaining means) 217, using a tweezer (substrate holding body) 111 of the substrate transfer machine 112 as a placement portion of the substrate 200.

The process furnace 202 is provided above and in a rear part of the housing 101. A lower end portion of the process furnace 202 is configured to be opened and closed with a furnace port shutter (furnace port opening/closing mechanism) 116. A boat elevator 121 serving as a lift mechanism for lifting the boat 217 to the process furnace 202 is provided below the process furnace 202, a seal cap 219 serving as a lid is horizontally installed on a lift member 122 serving as a connecting tool connected to a lift of the boat elevator (substrate holder elevating mechanism) 121, and the seal cap 219 is configured to vertically support the boat 217 and to be able to block the lower end portion of the process furnace 202. The boat 217 as a substrate holding means includes a plurality of boat column parts 221, and is configured to horizontally hold a plurality of the substrates 200 (for example, about 50 to 150 substrates) in a state of aligning the substrates 200 in the vertical direction with their centers aligned.

As illustrated in FIG. 4, a clean unit 118 constituted by a supply fan and a dustproof filter to supply clean air, which is an atmosphere obtained by cleaning outside air flowing in from a duct 124, is provided above the cassette shelf 109, and is configured to circulate clean air in the interior of the housing 101.

Next, an operation of the substrate processing apparatus 2 of the present disclosure will be described. As illustrated in FIG. 4, the cassette 100 is loaded through the cassette loading/unloading opening, and the substrates 200 are placed on the cassette stage 105 in the vertical posture and such that the substrate loading/unloading port of the cassette 100 faces upward. Thereafter, the cassette 100 is rotated clockwisely in the longitudinal direction by 90° toward the rear of the housing to make the substrates 200 in the cassette 100 in the horizontal posture and the substrate loading/unloading port of the cassette 100 face the rear of the housing by the cassette stage 105. Next, the cassette 100 is automatically transferred to a designated shelf position of the cassette shelf 109 or the spare cassette shelf 110, passed, temporarily stored, and then transferred from the cassette shelf 109 or the spare cassette shelf 110 to the transfer shelf 123, or is directly transferred to the transfer shelf 123.

When the cassette 100 is transferred to the transfer shelf 123, the substrate 200 is picked up from the cassette 100 by the tweezer 111 of the substrate transfer machine 112 through the substrate loading/unloading port and charged in the boat 217. The substrate transfer machine 112 having transferred the substrate 200 to the boat 217 returns to the cassette 100 and charges the next substrate 200 into the boat 217.

When the number of substrates 200 designated in advance is charged on the boat 217, the lower end portion of the process furnace 202 closed with the furnace port shutter 116 is opened with the furnace port shutter 116. Next, the boat 217 holding the substrate 200 group is loaded into the process furnace 202 as the seal cap 219 is lifted by the boat elevator 121.

After the loading, arbitrary processing is performed on the substrates 200 in the process furnace 202. After the processing, the substrates 200 and the cassette 100 are paid out to an outside of the housing 101 by a reverse procedure from the above-described procedure.

Next, the above-mentioned process furnace 202 will be described in detail with reference to FIGS. 5 and 6. FIG. 5 is a schematic configuration diagram of a vertical substrate process furnace preferably used in an embodiment of the present disclosure, and illustrates the process furnace 202 portion in a vertical cross section. FIG. 6 is a schematic configuration diagram of the vertical substrate process furnace preferably used in an embodiment of the present disclosure, and illustrates the process furnace 202 portion in a cross section.

The substrate processing apparatus 2 used in the present embodiment includes the main controller 300 having the controller 310 (see FIG. 2). The operation of each section included in the substrate processing apparatus 2 and the process furnace 202 is controlled by the main controller 300.

A reaction tube 203 is provided inside a heater 207, which is a heating device (heating means), as a reaction vessel for processing the substrates 200, a lower end opening of the reaction tube 203 is hermetically closed by a seal cap 219, which is a lid, through an O-ring 220 which is an airtight member, and the process chamber 201 is formed by at least the reaction tube 203 and the seal cap 219. The boat 217 which is a substrate holding means is erected on the seal cap 219 via a boat support base 218. The boat support base 218 serves as a holding body for holding the boat 217. Then, the boat 217 is inserted into the process chamber 201. In the boat column parts 221 of the boat 217, the plurality of substrates 200, which is to undergo patch processing, is stacked in the horizontal posture in multiple stages in a tube axis direction. The heater 207 heats the substrates 200 inserted in the process chamber 201 to a predetermined temperature.

Two gas supply pipes 232a and 232b serving as supply paths for supplying a plurality of types, here two types of gas are provided to the process chamber 201. Here, reactant gas is supplied to the process chamber 201 from the first gas supply pipe 232a via a first mass flow controller 241a which is a flow rate control device (flow rate control means) and a first valve 243a which is an on-off valve and further via a buffer chamber 237 formed in the reaction tube 203 to be described later, and reactant gas is supplied to the process chamber 201 from the second gas supply pipe 232b via a second mass flow controller 241b which is a flow rate control device (flow rate control means), a second valve 243b which is an on-off valve, a gas reservoir 247, and a third valve 243c which is an on-off valve, and further via a gas supply portion 249 to be described later.

The process chamber 201 is connected to a vacuum pump 246, which is an exhaust device (exhaust means), via a fourth valve 243d by a gas exhaust pipe 231 for exhausting gas, and is vacuum-exhausted. In addition, the fourth valve 243d is an on-off valve that can open and close a valve to vacuum-exhaust the process chamber 201 and stop vacuum exhaust, and can further adjust the degree of valve opening to adjust pressure.

In an arcuate space between the substrates 200 and an inner wall of the reaction tube 203 included in the process chamber 201, a buffer chamber 237, which is a gas dispersion space, is provided in a stacking direction of the substrates 200 on the inner wall of the reaction tube 203 from a lower portion to an upper portion, and a first gas supply hole 248a, which is a supply hole for supplying gas, is provided at an end of a wall of the buffer chamber 237 adjacent to the substrates 200. The first gas supply hole 248a opens toward a center of the reaction tube 203. The first gas supply hole 248a has the same opening area from the lower portion to the upper portion and is further provided at the same opening pitch.

At an end of the buffer chamber 237 on the opposite side from the end thereof at which the first gas supply hole 248a is provided, a nozzle 233 is arranged along the stacking direction of the substrates 200 from the lower portion to the upper portion of the reaction tube 203. The nozzle 233 is provided with a second gas supply hole 248b, which is a supply hole for supplying a plurality of gases. When a differential pressure between the buffer chamber 237 and the process chamber 201 is small, the opening area of the second gas supply hole 248b may have the same opening area and the same opening pitch from the upstream side to the downstream side of the gas. However, when the differential pressure is large, it is advisable to increase the opening area from the upstream side to the downstream side or decrease the opening pitch.

In the present embodiment, the opening area of the second gas supply hole 248b is gradually increased from the upstream side to the downstream side. With this configuration, even though there is a difference in the flow velocity of the gas from each second gas supply hole 248b, the gas having almost the same flow rate is ejected to the buffer chamber 237. Then, in the buffer chamber 237, after a difference in particle velocity of the gas ejected from each second gas supply hole 248b is relaxed, the gas is ejected from the first gas supply hole 248a into the process chamber 201. Therefore, the gas ejected from each second gas supply hole 248b can be a gas having a uniform flow rate and flow velocity when ejected from each first gas supply hole 248a.

Further, in the buffer chamber 237, a first rod-shaped electrode 269, which is a first electrode having an elongated structure, and a second rod-shaped electrode 270, which is a second electrode, are arranged by being protected by an electrode protection tube 275, which is a protection tube that protects the electrodes from the upper portion to the lower portion, either one of the first rod-shaped electrode 269 or the second rod-shaped electrode 270 is connected to a high-frequency power supply 273 via a matching portion 272, and the other one is connected to the ground which is a reference potential. As a result, plasma is generated in a plasma generation region 224 between the first rod-shaped electrode 269 and the second rod-shaped electrode 270.

The electrode protection tube 275 has a structure in which each of the first rod-shaped electrode 269 and the second rod-shaped electrode 270 can be inserted into the buffer chamber 237 in a state of being isolated from the atmosphere of the buffer chamber 237. Here, when the inside of the electrode protection tube 275 has the same atmosphere as the outside air (atmosphere), each of the first rod-shaped electrode 269 and the second rod-shaped electrode 270 inserted into the electrode protection tube 275 is oxidized by heating of the heater 207. Therefore, the inside of the electrode protection tube 275 is provided with an inert gas purge mechanism for filling or purging the inside with an inert gas such as nitrogen to sufficiently suppress the oxygen concentration at a low value, thereby preventing oxidation of the first rod-shaped electrode 269 or the second rod-shaped electrode 270.

Further, the gas supply portion 249 is provided on the inner wall at a position apart from a position of the first gas supply hole 248a by about 120° around an inner circumference of the reaction tube 203. The gas supply portion 249 is a supply portion that shares a gas supply type with the buffer chamber 237 when a plurality of types of gas is alternately supplied to the substrates 200 one by one in film formation using an ALD method.

Similarly to the buffer chamber 237, this gas supply portion 249 has a third gas supply hole 248c, which is a supply hole for supplying gas at the same pitch at a position adjacent to the substrates 200, and the second gas supply pipe 232b is connected thereto in the lower portion.

When a differential pressure between the inside of the gas supply portion 249 and the inside of the process chamber 201 is small, the opening area of the third gas supply hole 248c may have the same opening area and the same opening pitch from the upstream side to the downstream side of the gas. However, when the differential pressure is large, it is advisable to increase the opening area from the upstream side to the downstream side or decrease the opening pitch. In the present embodiment, the opening area of the third gas supply hole 248c is gradually increased from the upstream side to the downstream side.

The boat 217 having the boat column parts 221 on which the plurality of substrates 200 is placed in multiple stages at the same interval is provided in a central portion of the reaction tube 203, and this boat 217 can enter and exit the reaction tube 203 by a boat elevator mechanism omitted in the figure. Further, to improve uniformity of processing, a boat rotation mechanism 267, which is a rotation device (rotation means) for rotating the boat 217, is provided, and the boat 217 held by the boat support base 218 is rotated as the boat rotation mechanism 267 is rotated.

The main controller 300 serving as a control means is connected to the first and second mass flow controllers 241a and 241b, the first to fourth valves 243a, 243b, 243c, and 243d, the heater 207, the vacuum pump 246, the boat rotation mechanism 267, a boat elevating mechanism (not illustrated), the high-frequency power supply 273, and the matching portion 272 to perform flow rate adjustment of the first and second mass flow controllers 241a and 241b, an opening and closing operation of the first to third valves 243a, 243b, and 243c, an opening and closing and pressure adjustment operation of the fourth valve 243d, temperature adjustment of the heater 207, start and stop of the vacuum pump 246, rotation speed adjustment of the boat rotation mechanism 267, lifting and lowering operation control of the boat lifting mechanism, power supply control of high-frequency power supply 273, and impedance control by the matching portion 272.

As described above, the substrate processing system 1 of the present embodiment includes the substrate processing apparatus 2 provided with the process chamber 201 for processing the substrates 200 housed therein, the atmospheric pressure measurer 500 that periodically collects atmospheric pressure data in parallel with the processing of the substrates 200, the adjustor 430 that adjusts the processing condition of the substrates 200 using the atmospheric pressure data collected by the atmospheric pressure measurer 500, and the controller 310 that performs control of the processing of the substrates 200 in the substrate processing apparatus 2 according to the adjusted processing condition. That is, the recipe data is owned by the memory 320 of the main controller 300, and the group management apparatus 400 can refer to and rewrite the recipe data via the network. The adjustor 430 of the group management apparatus 400 refers to the step time adjustment model (hereinafter abbreviated as “STA”) stored in the memory 420 from the atmospheric pressure data measured by the atmospheric pressure measurer 500, and adjusts the recipe data.

In addition, a control program of the substrate processing apparatus that causes, by a computer, the substrate processing apparatus 2 to perform a condition acquisition procedure for acquiring the processing conditions of the substrates 200, a substrate processing procedure for processing the substrates 200 according to the acquired processing condition of the substrates 200, a data collection procedure for periodically collecting atmospheric pressure data in parallel with the substrate processing procedure, and an adjustment procedure for adjusting the processing condition of the substrates 200 based on the collected atmospheric pressure data is stored in the memory 320 or the external memory 340 of the main controller 300 or a non-transitory computer-readable recording medium.

(2) Recipe Data Adjusting Method

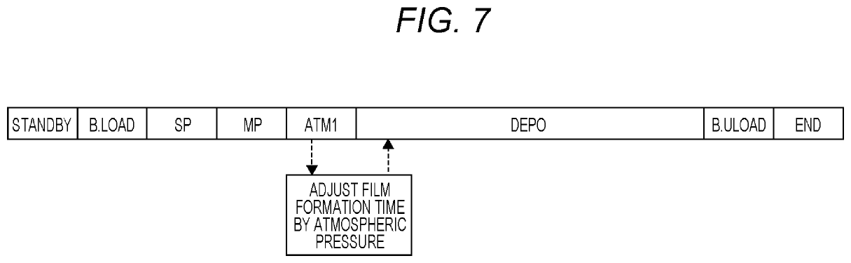

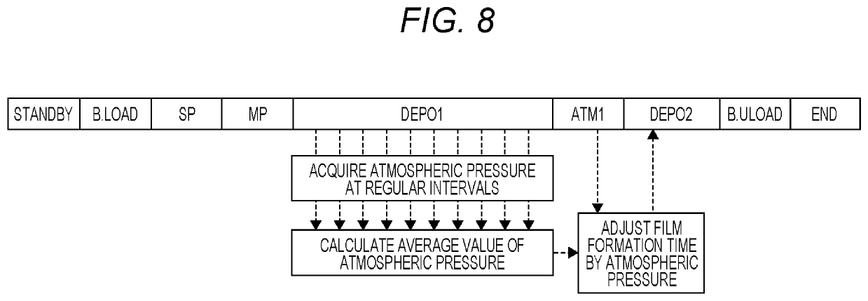

Before describing the recipe data adjusting method in the present embodiment, an example of a generally performed recipe data adjusting method will be described with reference to a conventional film formation process illustrated in FIG. 7. Here, FIG. 7 illustrates that each of the described steps is executed in chronological order from left to right, which is similarly applied to FIG. 8 described later.

First, when the controller 310 of the main controller 300 acquires the required recipe data from the memory 320, the substrate 200 is loaded on the boat 217 in a preparation (STANDBY) step (see FIG. 4). When the film formation process is prepared, the boat 217 holding the substrate 200 is then loaded into the process chamber 201 in a boat loading (B.LOAD (=Boat LOADing)) step. Then, the vacuum pump 246 is operated, a slow exhaust (SP (=Slow Purge)) step and then a main exhaust (MP (=Main Purge)) step are executed through the gas exhaust pipe 231 (see FIGS. 5 and 6), and the inside of the process chamber 201 is in a vacuum state.

Here, an atmospheric pressure adjustment (ATM1 (=ATMosphere)) step, which is a step that triggers adjustment of the film formation time in the recipe data, is executed. In this step, the group management apparatus 400 calculates an optimum film formation time at the present time with reference to the STA from current atmospheric pressure data measured by the atmospheric pressure measurer 500. Then, after the adjustor 430 rewrites the film formation time of the recipe data with the calculated film formation time, film-forming gas is supplied to the process chamber 201 through each of the gas supply holes 248a, 248b, and 248c (see FIG. 6) during this calculated film formation time in a film formation (DEPO (=DEPOsit)) step, and a semiconductor device subjected to a film formation process on the substrates 200 is manufactured. When the film formation time elapses, supply of the film-forming gas is suspended to release the vacuum state in the process chamber 201, then the boat 217 filled with the substrates 200 becoming semiconductor devices by being subjected to film formation is unloaded from the process chamber 201 by a boat unloading (B.ULOAD (=Boat UnLOADing)) step, and the film formation process ends (END).

As described above, in the recipe data adjusting method illustrated above, the optimum film formation time is calculated at that time before start of the DEPO step, and the film formation time in the recipe data is rewritten. However, since this rewriting is performed only once before the start of the DEPO step, even when the atmospheric pressure fluctuates after the start of the DEPO step, it is difficult to adjust the film formation time according to the fluctuating atmospheric pressure, and an expected film formation result may not be obtained.

In contrast with the above-mentioned example of the recipe data adjusting method generally performed, an example of the recipe data adjusting method in the present embodiment will be described with reference to FIGS. 8 and 3. First, the STANDBY step, the B.LOAD step, the SP step, and the MP step after the controller 310 of the main controller 300 acquires the required recipe data from the memory 320 are the same as those of the conventional adjusting method.

Then, in a first film formation (DEPO1) step, film-forming gas is supplied to the process chamber 201 and the film formation process is performed on the substrates 200 during a part of the film formation time (for example, 90%) in the acquired recipe data. In parallel with this step, the controller 410 of the group management apparatus 400 acquires the atmospheric pressure data measured by the atmospheric pressure measurer 500 at regular intervals (for example, every second), and stores this data as device data in the memory 420 each time the data is acquired. Then, at the end of the DEPO1 step, an average value of the stored atmospheric pressure data is calculated.

Next, in an ATM1 step, the group management apparatus 400 refers to the STA and calculates a film formation time corresponding to the average value of the calculated atmospheric pressure data. Then, after the adjustor 430 calculates an adjusted film formation time obtained by subtracting the previously elapsed film formation time from the calculated film formation time, during this adjusted film formation time, a second film formation (DEPO2) step is executed in the same manner as the DEPO1 step, and a semiconductor device subjected to a film formation process on the substrate 200 is manufactured. Then, a B.ULOAD step is executed in the same manner as described above, and the film formation process ends (END).

As described above, in the adjusting method of the present embodiment, the film formation time of the recipe data can be adjusted according to the fluctuation of the atmospheric pressure during the film formation step. Thus, in particular, even when the film formation time is long, it is possible to obtain a semiconductor device having the expected film formation result. Note that, in the above example, the film formation step is divided into a first half and a second half, an average value obtained in the first half is applied to the STA to calculate the optimum film formation time, and a time in the second half is adjusted based thereon. For example, a ratio of the first half to the second half can be 9:1 as described above. However, it is obvious that the ratio is not fixed thereto, and can be adjusted according to the length of the film formation time in the recipe data. In addition, since the average value of the atmospheric pressure data in the first half of the film formation time of the recipe data is used to calculate the optimum film formation time, the larger the ratio of the first half, the closer to the optimum film formation time. On the other hand, when the second half becomes excessively short, the time required for adjustment may be insufficient. Therefore, it is necessary to appropriately set the ratio of the first half to the second half. Note that, when the optimum film formation time has already passed in the first half of the film formation time, it is possible to omit the film formation time in the second half and end the film formation process.

(3) Step Time Adjustment Model (STA)

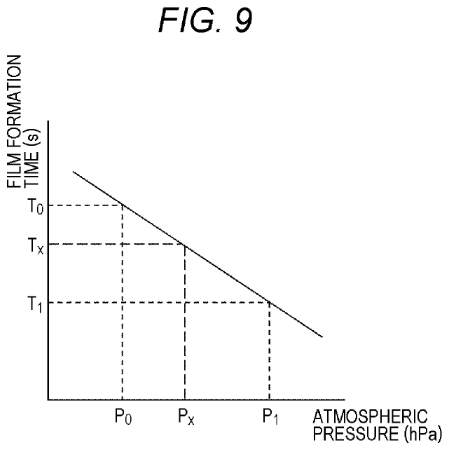

The step time adjustment model (STA) mentioned above will be described in detail with reference to FIG. 9. Normally, the recipe data is created on the assumption that the atmospheric pressure at the time of film formation is 1 atm (1013 hPa). Therefore, when the atmospheric pressure is not 1 atm at the start of the film formation process, a deposition rate on the substrates 200 will naturally be different from a deposition rate expected in the recipe data. Thus, it is necessary to amend the film formation time in consideration of this point. A relationship between the atmospheric pressure value at the start of film formation and the optimum film formation time therefor can be modeled, and the model is the STA. However, since the STA does not take into consideration conditions other than film formation time, such as temperature and pressure during film formation, it is a prerequisite to make such conditions the same and use the conditions. Therefore, using in combination with the recipe is necessary.

This model is a graph of a linear function that derives the optimum film formation step time for the atmospheric pressure value, and by using this model, it is possible to amend the film formation time to the optimum film formation time and perform film formation even at the atmospheric pressure other than 1 atm. Here, it is assumed that a reference pressure (for example, 1 atm) is P0, and the optimum film formation time at this time is T0 (for example, 3600 seconds). Note that this T0 is the film formation time set in the recipe data and serves as the reference for this model. Further, an appropriate atmospheric pressure value other than P0 (for example, 1100 hPa) is set as P1, and the optimum film formation time (for example, 3684 seconds) corresponding thereto is determined in advance and defined as T1. In addition, a graph of a linear function passing through two points (P0, T0) and (P1, T1) is the STA. Based on this STA, the optimum film formation time TX for the atmospheric pressure PX obtained in the ATM1 step can be calculated by the following Equation (1).

TX={(T0−T1)PX+(T1P0−T0P1)}/(P0−P1) Equation (1)

Then, when the average value of the atmospheric pressure obtained in the DEPO1 step of FIG. 8 is substituted into PX of the above Equation (1), TX serving as an adjusted film formation time can be obtained.

However, when the thickness of the film required for the semiconductor device is different, the film formation time with respect to the reference atmospheric pressure P0 may be different from the above-mentioned T0. When the film formation time different from T0 is T0′, the optimum film formation time TX′ for the atmospheric pressure PX obtained in the ATM1 step can be obtained by the following Equation (2) after obtaining TX using the above Equation (1).

TX′=TX(T0′/T0)+T0′ Equation (2)

For example, in the STA, in the case where the film formation time T0 for P0 at 1 atm (1013 hPa) is 3600 seconds, when an attempt is made to manufacture a semiconductor device having a thickness of a film at which a film formation time (T0′) for the same P0 is 7200 seconds,

T0′/T0=7200/3600=2.

Therefore, the film formation time TX for the atmospheric pressure PX obtained in the ATM1 step may be first obtained by Equation (1), and then applied to Equation (2), thereby obtaining the optimum film formation time TX′ for this semiconductor device as follows:

TX′=2TX+T0′.

From the above description, it is possible to apply the same STA to recipe data having a different film formation time with respect to the reference atmospheric pressure P0, and to obtain an optimum film formation time according to a fluctuation of the atmospheric pressure.

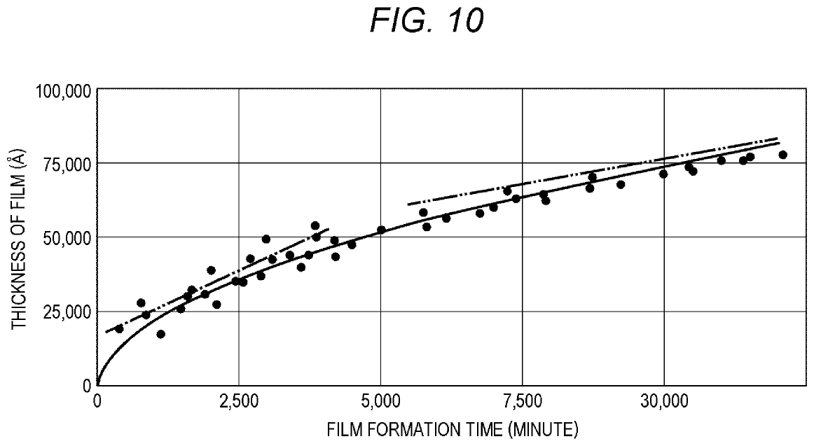

It should be noted that the STA is obtained as a result of experimentally obtaining results of thicknesses of the film obtained for various film formation times under the same conditions except for the film formation time. For example, in an experimental result illustrated in FIG. 10, the film formation time and the thickness of the film are not in a proportional relationship, and an inclination is steep at a short film formation time. However, as the film formation time becomes longer, the inclination becomes gentler.

Referring to the STA used in the present disclosure, the model is created from an experimental result of the step time and the film thickness result. However, as illustrated in FIG. 10, a relationship between an oxide film and time is not completely proportional, and a curve having a steep rising edge and a stable second half is drawn. Thus, when the model is generated, data suitable for a long-term recipe needs to be used. From this description, in FIG. 10, in two approximate curves on left and right sides, an approximate straight line on the right side is adopted.

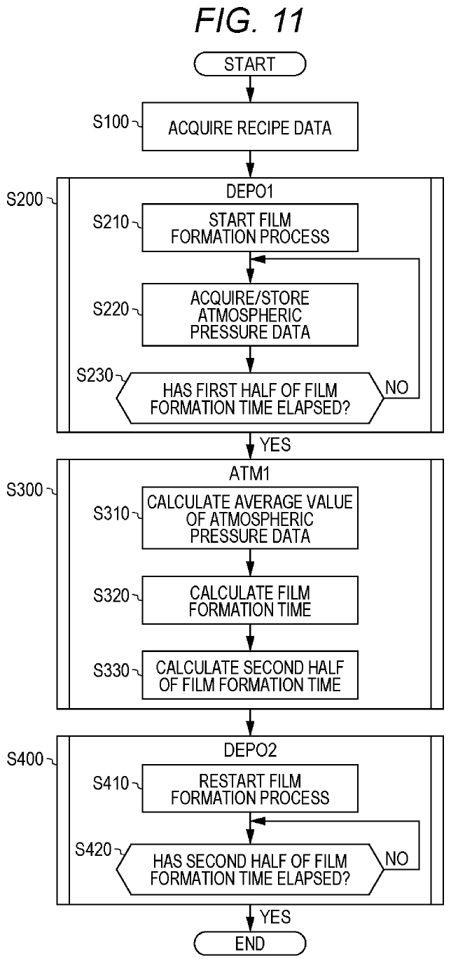

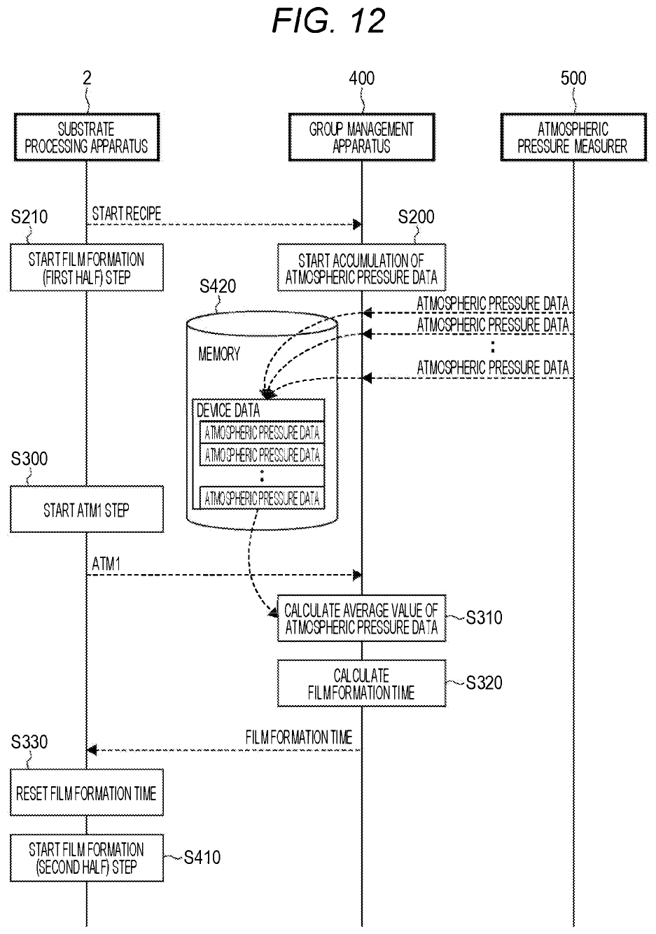

Hereinafter, a method of manufacturing a semiconductor device of the present embodiment will be described with reference to a flowchart of FIG. 11 and a sequence diagram of FIG. 12.

The method of manufacturing the semiconductor device of the present embodiment includes a condition acquisition process (S100) in which a processing condition of the substrate is acquired, a substrate processing process (S200) in which the substrate is processed according to the acquired substrate processing condition, a data collection process (S220) in which atmospheric pressure data is periodically collected in parallel with the substrate processing process, and an adjustment process (S300) in which the substrate processing condition is adjusted based on the collected atmospheric pressure data. Then, the substrate processing process is continued under the adjusted processing condition (S400). Here, in the adjustment process, the substrate processing condition, which is obtained by applying an average value of the collected atmospheric pressure data to a pre-created model (see FIG. 9), is reacquired (S330).

Note that, when the predetermined condition is fulfilled, the substrate processing process is interrupted (S230). After interruption of the substrate processing process, the substrate processing condition is reacquired in the adjustment process (S330), and the substrate processing process is restarted according to the reacquired substrate processing condition (S410). It should be noted that this predetermined condition is either elapse of a predetermined time from start of processing of the substrate processing process or elapse of a time corresponding to a predetermined ratio with respect to a required time of the substrate processing process (S230).

More specifically, first, at a stage illustrated in S100, a condition acquisition process of acquiring recipe data serving as a substrate processing condition from the memory 320 by the controller 310 is executed in the substrate processing apparatus 2.

Next, in the DEPO1 step of S200 (see FIG. 8), at a stage illustrated in S210, in the substrate processing process in which the substrate is processed according to the acquired recipe data, the first half of the film formation time is started by the substrate processing apparatus 2. Here, the film formation time recorded as a part of the recipe data is divided into a first half and a second half, and in the DEPO1 step, the film formation process is performed over the first half time. The first half and the second half may be divided at a predetermined ratio (for example, 9:1), or the first half may be a predetermined time and the remaining time may be the second half.

In parallel with the substrate processing process being performed, at a stage illustrated in S200, a data collection process in which the group management apparatus 400 periodically (for example, every second) collects atmospheric pressure data from the atmospheric pressure measurer 500, is executed. The collected atmospheric pressure data is stored in the memory 420 of the group management apparatus 400 (see FIG. 12).

Then, at a stage illustrated in S230, the controller 410 determines whether or not the first half of the film formation time has elapsed as a predetermined condition. When it is determined that the time has not elapsed, the film formation process and acquisition and storage of the atmospheric pressure data are continued. On the other hand, when it is determined that the first half of the film formation time has elapsed, the substrate processing process is interrupted, assuming that the predetermined condition is fulfilled, and the process proceeds to the ATM1 step of S300 (see FIG. 8) to execute an adjustment step in which the substrate processing condition is adjusted based on the collected atmospheric pressure data.

In the adjustment process, first, at a stage illustrated in S310, the adjustor 430 of the group management apparatus 400 adjusts the film formation time serving as the substrate processing condition. Specifically, the average value of the atmospheric pressure data stored in the memory 420 is calculated. Next, at a stage illustrated in S320, this average is applied to the STA, which is a pre-created model (see FIG. 9), to calculate the film formation time, which is the substrate processing condition. Further, at a stage illustrated in S330, the time in the second half is calculated by subtracting the time in the first half in which the film formation process has already been executed from the calculated film formation time. The calculated time in the second half is transmitted from the communicator 450 of the group management apparatus 400 to the communicator 350 of the substrate processing apparatus 2, and the controller of the substrate processing apparatus 2 resets the film formation time by the time in the second half.

Note that, when acquisition of the atmospheric pressure data stored in the memory 420 fails, or when storage of the atmospheric pressure data fails, 1 atmosphere is treated as the average value of the atmospheric pressure data during calculation of the average value of the atmospheric pressure data in S310.

In a DEPO2 step of the S400 (see FIG. 8), the substrate processing apparatus 2 reacquires this adjusted processing condition, that is, the time in the second half, and at a stage illustrated in S410, the interrupted substrate processing process is restarted according to this processing condition. The restarted substrate processing process is continued until elapse of the time in the second half is determined at a stage illustrated in S420.

As described above, in the present embodiment, the film formation time of the recipe data is divided into the first half and the second half. In the first half, the atmospheric pressure data is acquired and stored at the same time as the film formation process is performed. When the first half ends, the film formation time is adjusted based on the atmospheric pressure data, and the film formation time in the second half is calculated from the adjusted film formation time. Then, during the time of the second half, the film formation process is continued again. As described above, the film formation time of the second half can be adjusted according to the change in atmospheric pressure generated during the first half of the film formation process. Therefore, even when the atmospheric pressure changes during the film formation process, it is possible to manufacture a semiconductor device having a desired thickness of the film.

According to the present disclosure, it is possible to obtain an expected film formation result by causing a recipe to correspond to a fluctuation of atmospheric pressure generated during a film formation process.

What is claimed is:

1. A method of manufacturing a semiconductor device, the method comprising:
processing a substrate according to a processing condition of the substrate;
collecting atmospheric pressure data in parallel with the processing of the substrate;
adjusting the processing condition of the substrate using the collected atmospheric pressure data; and
performing control of the substrate processing according to the processing condition.

2. The method according to claim 1, wherein the processing condition is defined in a step of processing the substrate, and the step is defined by a recipe having at least one.

3. The method according to claim 2, wherein the processing condition has a time to perform processing of the step.

4. The method according to claim 1, wherein the processing of the substrate is continued under the adjusted processing condition.

5. The method according to claim 1, wherein the processing of the substrate includes acquiring the atmospheric pressure data at regular intervals.

6. The method according to claim 1, wherein the adjusting of the processing condition of the substrate includes:
calculating an average value from the atmospheric pressure data;
acquiring a film formation time from the calculated average value of the atmospheric pressure data and a pre-created model; and
reacquiring a processing condition of the substrate from the acquired film formation time.

7. The method according to claim 6, wherein the pre-created model is created from an experimental result of a step time and a film thickness result.

8. The method according to claim 6, wherein
the processing of the substrate is interrupted when a predetermined condition is fulfilled,
a processing condition of the substrate is reacquired in the adjusting of the processing condition of the substrate after interrupting the processing of the substrate, and
the processing of the substrate is restarted according to the reacquired processing condition of the substrate.

9. The method according to claim 6, wherein the processing condition is a remaining time of the processing of the substrate, which is obtained by subtracting a time until the processing of the substrate is interrupted from the acquired film formation time.

10. The method according to claim 6, wherein, when the acquired film formation time is the same as or shorter than the time until the processing of the substrate is interrupted, the processing of the substrate is ended.

11. The method according to claim 8, wherein the predetermined condition is either elapse of a predetermined time from start of the processing of the substrate or elapse of a time corresponding to a predetermined ratio with respect to a required time of the processing of the substrate.

12. The method according to claim 8, wherein the predetermined ratio is a time less than 90% of the required time of the processing of the substrate.

13. The method according to claim 1, wherein, when collection or acquisition of atmospheric pressure data fails, a reference atmospheric pressure is treated as an average value of the atmospheric pressure data and applied to a pre-created model, thereby reacquiring a processing condition of the substrate.

14. A substrate processing system comprising:
a substrate processing apparatus provided with a process chamber for processing a substrate;
an atmospheric pressure measurer configured to collect atmospheric pressure data in parallel with the processing of the substrate;
an adjustor configured to adjust a processing condition of the substrate using the atmospheric pressure data collected by the atmospheric pressure measurer; and
a controller configured to perform control of the processing of the substrate in the substrate processing apparatus according to the adjusted processing condition.

15. A non-transitory computer-readable recording medium storing a program that causes, by a computer, a substrate processing apparatus to perform a process comprising:
processing a substrate according to a processing condition of the substrate;
collecting atmospheric pressure data in parallel with the processing of the substrate;
adjusting the processing condition of the substrate using the collected atmospheric pressure data; and
performing control of the substrate processing according to the processing condition.
